(19) United States
(12) Patent Application Publication
(10) Pub. No.: US 2026/0371473 A1
(43) Pub. Date: Nov. 19, 2026

(54) BONDING MEMBER AND SEMICONDUCTOR DEVICE

(71) Applicant: Mitsubishi Electric Corporation, Tokyo (JP)

(72) Inventors: Koji YAMAZAKI, Chiyoda-ku, Tokyo (JP); Norikazu SAKAI, Chiyoda-ku, Tokyo (JP)

(73) Assignee: Mitsubishi Electric Corporation, Tokyo (JP)

(21) Appl. No.: 18/995,934

(22) PCT Filed: Sep. 29, 2022
(86) PCT No.: PCT/JP2022/036485

§ 371 Date: Jan. 17, 2025

(51) Int. Cl. H05K 1/02; B23K 35/02; B23K 35/26; B23K 35/30; B23K 101/42; H05K 1/181

(52) U.S. Cl. CPC H05K 1/0203; B23K 35/0233; B23K 35/262; B23K 35/3033; H05K 1/181; B23K 2101/42; H05K 2201/066

(57) ABSTRACT

A bonding member bonded a first target object and a second target object includes: a metal particle containing Ni; a low melting-point phase containing Sn and having a melting point of less than 300 °C; and an intermetallic compound having a melting point of 300 °C or more and resulting from interdiffusion between Sn and the metal particle. A ratio of an amount of the low melting-point phase to a total amount of the bonding member is 2 volume % or more and less than 20 volume %. Each of thermal expansion coefficients of the first target object and the second target object is 3×10⁻⁶/K or more and less than 13×10⁻⁶/K, and a difference between the thermal expansion coefficient of the first target object and that of the second target object is less than 5×10⁻⁶/K. A thermal expansion coefficient of the bonding member is 16×10⁻⁶/K or more and less than 20×10⁻⁶/K.

### TECHNICAL FIELD

The present disclosure relates to a bonding member and a semiconductor device.

### BACKGROUND ART

In recent years, there has been an increasing demand for reliability of a semiconductor device. In particular, it has been required to improve reliability of life for a bonded portion between components having different thermal expansion coefficients (for example, a bonded portion between a semiconductor element and a circuit board, or a bonded portion between a circuit board and a heat radiation plate).

Conventionally, semiconductor elements each having a substrate employing silicon (Si), gallium arsenide (GaAs), or the like have been widely used. An operation temperature of each of such semiconductor elements is 100 °C to 125 °C. A solder material used for bonding between the semiconductor element and the circuit board is required to have: a high melting point to cope with multi-stage solder bonding at the time of manufacturing; cracking resistance against repeated thermal stress caused by starting and stopping; and device contamination resistance.

In response to these demands, for example, 95Pb-5Sn (mass %) has been used as a solder material for Si devices, and 80Au-20Sn (mass %) has been used as a solder material for gallium arsenide devices.

However, 95Pb-5Sn, which contains a large amount of harmful lead (Pb), has a problem from the viewpoint of reducing environmental load. On the other hand, 80Au-20Sn, which contains a large amount of noble metal, has a problem from the viewpoint of increased price or reserved amount of noble metal. Therefore, alternative materials for both of them have been strongly desired.

On the other hand, from the viewpoint of energy saving, a device having a substrate employing silicon carbide (SiC) or gallium nitride (GaN) has been actively developed as a next-generation device. An operation temperature of each of these is 175 °C or more, and is said to be 300 °C in future.

This means that the temperature of the bonded portion between the semiconductor element and the circuit board becomes 175 °C. Further, the temperature of the bonded portion between the circuit board and the heat radiation plate is also increased to a temperature close thereto depending on an operation condition and a heat radiation performance. Therefore, high reliability is required for the bonded portion between the circuit board and the heat radiation plate as well as the bonded portion between the semiconductor element and the circuit board.

As described above, a member (bonding member) that has a high melting point and excellent heat resistance and that forms each of the bonded portions has been required in each of the conventional and next-generation devices.

As a conventional method of producing a bonding body having high heat resistance, the following method has been known: a large amount of metal particles such as Ag or Cu are added to Sn and a bonding layer is formed by an Ag—Sn alloy phase (for example, Ag₃Sn: melting point of 480 °C), a Cu—Sn alloy (for example, Cu₆Sn₅: melting point of 415 °C; Cu₃Sn: melting point of 676 °C), or the like through metal diffusion resulting from heating (300 °C or less) at the time of bonding.

Regarding a connection method or electronic device using solder, for example, PTL 1 (Japanese Patent Laying-Open No. 2002-314241) discloses a bonding structure in which Sn of a solder ball is melted to form an intermetallic compound at an interface with Cu of metal balls and the metal balls of Cu are coupled together. It should be noted that since the melted Sn also forms intermetallic compounds with an electrode of a semiconductor chip, an electrode of an intermediate substrate, and the like, the metal balls of Cu and those electrodes are coupled.

Further, PTL 1 describes that a connection portion can sufficiently secure strength to withstand a process at the time of subsequent solder connection even when Sn of the solder ball becomes a Cu—Sn intermetallic compound (Cu₆Sn₅; melting point: about 630 °C) to increase the melting points of a contact portion and the vicinity thereof and a part of Sn remains unless the other parts are melted.

It should be noted that PTL 1 also describes that: each of the metal balls is not limited to Cu; Ag, Au, Al, Ni, a Cu alloy, a Cu—Sn compound, a Ag—Sn compound, an Au—Sn compound, an Al—Ag compound, a Zn—Al compound, or the like may be used therefor; and Au has excellent wettability and therefore has a void reduction effect at the connection portion.

Further, PTL 2 (WO 2012/108395) describes that a solder containing a Sn-based metal and a Cu-based metal is heated and melted at a connection portion, thereby forming an intermetallic compound having a melting point of 310 °C or more. It should be noted that it is also disclosed that a ratio of the Sn-based metal component contained in the connection portion is 30 volume % or less.

### CITATION LIST

### Patent Literature

PTL 1: Japanese Patent Laying-Open No. 2002-314241
PTL 2: WO 2012/108395

### SUMMARY OF INVENTION

### Technical Problem

However, in the conventional method of manufacturing a semiconductor device as illustrated in each of PTL 1 and PTL 2, an amount of the metal particles added to the Sn particles are not evaluated with regard to cracking resistance in a thermal shock test.

For example, when a large amount of the metal particles such as Cu particles or Ag particles are added, fluidity of Sn is deteriorated and a portion sealed by the metal particles therefore becomes an unbonded portion to generate a void, with the result that a crack is likely to be generated when thermal shock is applied to the bonded portion.

Moreover, the Ag—Sn alloy represented by Ag₃Sn or the Cu—Sn alloy represented by Cu₆Sn₅ has about 5 mass % of a solid solution region of Ag or Cu and Sn in view of a metal phase diagram. However, since a state of separation of two phases is exhibited, an interface between Ag₃Sn and Cu₆Sn₅ becomes a void unless a Sn phase having a low melting point is present, and becomes a starting point of a crack.

On the other hand, the present inventors considered that in a semiconductor device that is operated at a high temperature, it is important to secure not only a mechanical property as a material or heat cycle resistance as a sole component applied thereto, but also reliability as a device in a power cycle (repeating of generation of heat and cooling by repeating ON and OFF of application of power to a semiconductor device) involving an actual operation.

An object of the present disclosure is to provide a bonding member having high bonding reliability for a power cycle in a semiconductor device that is operated at a high temperature.

### Solution to Problem

A bonding member bonds a first target object and a second target object.

The bonding member includes: a metal particle containing Ni as a main component; a low melting-point phase containing Sn as a main component and having a melting point of less than 300 °C; and an intermetallic compound having a melting point of 300 °C or more and resulting from interdiffusion between Sn and the metal particle.

A ratio of an amount of the low melting-point phase to a total amount of the bonding member is 2 volume % or more and less than 20 volume %.

Each of thermal expansion coefficients of the first target object and the second target object is 3×10⁻⁶/K or more and less than 13×10⁻⁶/K, and a difference between the thermal expansion coefficient of the first target object and the thermal expansion coefficient of the second target object is less than 5×10⁻⁶/K.

A thermal expansion coefficient of the bonding member is 16×10⁻⁶/K or more and less than 20×10⁻⁶/K.

### Advantageous Effects of Invention

According to the present disclosure, it is possible to provide a bonding member having high bonding reliability for a power cycle in a semiconductor device that is operated at a high temperature.

Specifically, in the bonding member of the present disclosure, the low melting-point phase (for example, a Sn-only phase) remains to secure wettability to a bonding-target member (bonding-target object), and a remaining amount thereof is optimized to suppress a vertical crack in the power cycle.

Further, since the bonding member of the present disclosure is applied to bond the plurality of bonding-target objects between which the difference in thermal expansion coefficient falls within the specific range, it is possible to suppress a lateral crack caused by a shear stress resulting from the difference between the thermal expansion coefficients of the plurality of bonding-target objects.

Further, since the bonding member having a thermal expansion coefficient falling within the specific range is employed, tensile stress and compressive stress (tensile-compressive stress) caused by the difference between the thermal expansion coefficient of the bonding-target object and the thermal expansion coefficient of the bonding member are suppressed, thereby attaining excellent bonding reliability even in an operation at a high temperature (for example, 175 °C).

### BRIEF DESCRIPTION OF DRAWINGS

FIG. 1 is a flowchart showing a procedure of manufacturing a semiconductor device (bonding member).

FIG. 2 is a schematic cross sectional view showing a first step of FIG. 1.

FIG. 3 is a schematic cross sectional view showing a second step of FIG. 1.

FIG. 4 is a schematic cross sectional view showing a third step of FIG. 1.

FIG. 5 is a schematic cross sectional view showing a fourth step of FIG. 1.

FIG. 6 is a schematic cross sectional view showing a fifth step of FIG. 1.

### DESCRIPTION OF EMBODIMENTS

Hereinafter, embodiments of the present disclosure will be described. It should be noted that in the figures, dimensional relations such as length, width, thickness, and depth are appropriately changed for the sake of clarity and simplification of the figures, and do not represent actual dimensional relations.

### First Embodiment

### <Bonding Member>

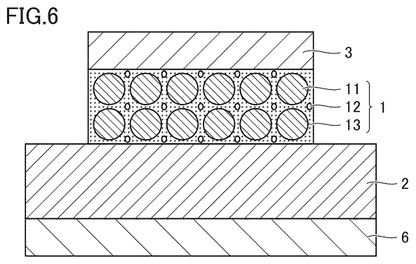

A bonding member 1 of the present embodiment is a member that bonds a first target object 2 (for example, a heat radiation plate) and a second target object 3 (for example, a circuit board having a semiconductor element and a wiring circuit) (see FIG. 6). It should be noted that bonding member 1 is different from a solder sheet 10 described later, and is a member that is composed of solder (solder alloy) solidified after being melted by a heating step and that is present in a state in which bonding member 1 is bonded to both of the bonding-target members (first target object 2 and second target object 3).

Bonding member 1 of the present embodiment includes metal particles 11, a low melting-point phase 12, and an intermetallic compound 13.

Each of metal particles 11 contains Ni as a main component. Here, the “main component” is a component having the largest amount among components contained in metal particle 11. The content ratio of Sn in metal particle 11 is preferably 60 mass % or more, is more preferably 70 mass % or more, and is further preferably 80 mass % or more.

Metal particle 11 can further contain at least one component selected from a group consisting of Fe, Cr, C, Cu, and Si.

Low melting-point phase 12 contains Sn as a main component and has a melting point of less than 300 °C. Here, the “main component” is a component having the largest amount among components contained in low melting-point phase 12. The content ratio of Sn in low melting-point phase 12 is preferably 60 mass % or more, is more preferably 70 mass % or more, and is further preferably 80 mass % or more.

The low melting-point phase can further contain, for example, Ag and Cu (in addition to Sn). In this case, for example, the content ratio of Ag may be 3 mass % or more and less than 4 mass %, and the content ratio of Cu may be 0.5 mass % or more and less than 1.0 mass %. It should be noted that when the content ratios of Ag and Cu respectively fall within these ranges, the effect of the present disclosure is expected to be more securely obtained.

Intermetallic compound 13 is a compound (phase) resulting from interdiffusion between Sn and metal particle 11, and has a melting point of 300 °C or more.

Further, in bonding member 1 of the present embodiment, a ratio of an amount of low melting-point phase 12 to a total amount of bonding member 1 is 2 volume % or more and less than 20 volume %.

Further, each of thermal expansion coefficients of first target object 2 and second target object 3 is 3×10⁻⁶/K or more and less than 13×10⁻⁶/K, and a difference between the thermal expansion coefficient of first target object 2 and the thermal expansion coefficient of second target object 3 is less than 5×10⁻⁶/K.

Further, a thermal expansion coefficient of the bonding member is 16×10⁻⁶/K or more and less than 20×10⁻⁶/K.

It should be noted that as a result of performing a reliability test on a semiconductor device in a power cycle, the present inventors have found that in the power cycle, suppression of cracks (vertical cracks) generated in the layer of the bonding member in a thickness direction is important for improvement of bonding reliability.

Further, the reliability of the bonded portion depends not only on the material of the bonding member such as solder but also on a configuration of a bonding-target member (bonding-target object). Therefore, in order to improve reliability of a power module, it is considered necessary to review not only the composition of the material of the bonding member but also the configuration of the bonding-target member.

It should be noted that regarding the vertical cracks, a reference document (Koji Yamazaki, “A Study on Vertical Crack Initiation of Lead-Free Solder Joints”, the 26th JIEP Annual Meeting, 9C-14) describes that when a high-speed heat cycle test (+50 °C/+175 °C; temperature difference: 125 °C) was performed on a sample in which Cu plates were solder-bonded to each other and a sample in which Mo plates were solder-bonded to each other, no vertical crack was generated in the former sample and a vertical crack was generated in the latter sample even though the same solder material was used in both the samples for the sake of the bonding.

This is associated with tensile stress and compressive stress (tensile-compressive stress) caused by a difference between the thermal expansion coefficient of the solder material and the thermal expansion coefficient of the bonding-target member. When restrained by a member having a low thermal expansion property, the tensile-compressive stress is applied to the solder having a large thermal expansion coefficient, and dynamic recrystallization further occurs in the solder due to heating, thus resulting in generation of a vertical crack along a grain boundary of Sn, which is a main component of the solder, or along an internal precipitate.

It should be noted that it has been known that when the difference between the thermal expansion coefficients of the bonding-target members (two bonding-target objects) is large, a lateral crack is mainly generated, rather than a vertical crack.

As a result of the above-described review, the present inventors have found the bonding member of the present disclosure having high bonding reliability for a power cycle in a semiconductor device that is operated at a high temperature.

### Second Embodiment

### <Semiconductor Device>

A semiconductor device according to the present embodiment includes a heat radiation plate 2 and a circuit board 3 (substrate having a semiconductor element and a wiring circuit). Heat radiation plate 2 and circuit board 3 are bonded with bonding member 1, which has high bonding reliability as described in the first embodiment, being interposed therebetween. Thus, a semiconductor device having high reliability is provided.

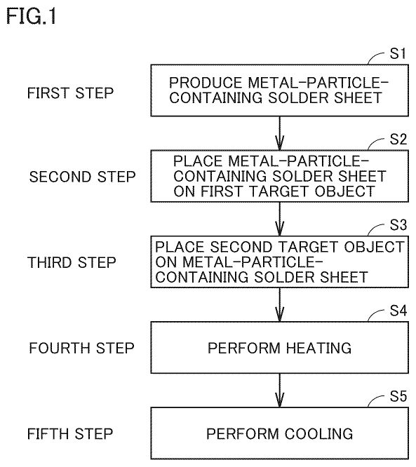

The semiconductor device of the present embodiment can be manufactured by a manufacturing method including a step of bonding the heat radiation plate and the circuit board (see FIGS. 1 to 6).

Referring to a flowchart shown in FIG. 1, the following describes an exemplary procedure of bonding the circuit board and the heat radiation plate in the method of manufacturing a semiconductor device according to the present embodiment.

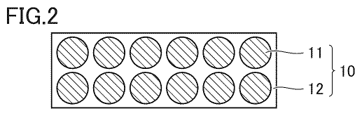

First, as a first step (S1), solder sheet 10, in which metal particles 11 each composed of Ni are dispersed in low melting-point phase 12 containing Sn as a main component and having a melting point of 300 °C or less, is cut into a predetermined size (see FIG. 2).

Specifically, as a representative example of the solder composition of low melting-point phase 12, a composition represented by Sn-3.3Ag-0.5Cu (the numerical values each represent mass % and Sn is the remainder of the composition ratios of the other elements) was attained by adding and dissolving each element, thereby producing a bulk body.

Next, solder sheet 10 in the form of a roll was produced to have a thickness of 100 μm through a rolling process at 100 °C or less.

Thereafter, Ni particles (metal particles 11) were uniformly dispersed in solder sheet 10 and a sheet composed of low melting-point phase 12 was overlapped therewith from above, thereby producing a mixed sheet. In the present embodiment, the thickness thereof was 100 μm, but it is not limited thereto. Further, the cut size thereof was 10 mm×10 mm, which was the same as that of the upper member.

It should be noted that apart from the rolling, solder sheet 10 may be manufactured by melting the bulk body and sequentially introducing the melted solder via a thin slit. Further, when more than three elements are combined as described above (for example, when Bi, In, Sb, or the like is added to Sn—Ag—Cu), the composition of the bulk body may become non-uniform due to a temperature variation in a melting furnace. In this case, the solder composition may be adjusted by first producing a bulk body of Sn—Ag—Cu, then dissolving it again, and adding a predetermined amount of the remainder of Bi, In, Sb, or the like. Alternatively, solder sheet 10 may be manufactured by first forming solder balls, uniformly dispersing the solder balls onto a flat plate, and performing compression molding.

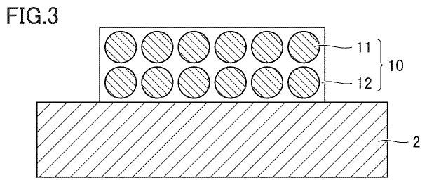

Next, as a second step (S2), solder sheet 10 is placed on first target object 2 (lower member) (see FIG. 3).

It should be noted that in order to prevent oxidation, a predetermined amount of an anticorrosive agent having a decomposition temperature of 100 °C or less, which does not affect the bonding property, may be applied to the outermost surface of the CuMo alloy plate. Further, when placing solder sheet 10, an organic agent, which is thermally decomposed at a high temperature of 100 °C or more, may be used as a tack material so as to avoid solder sheet 10 from being deviated from a predetermined position. The viscosity of the tack material is preferably 200 Pa's or more. Alternatively, a resist film may be applied to portions other than the bonded portion of first target object 2 so as to avoid solder sheet 10 from being deviated.

Solder sheet 10 may be slightly curved at the time of cutting or handling. This is due to the following reason: because solder sheet 10 is melted to some extent by heating, an influence by the initial shape of the solder sheet is small. However, when solder sheet 10 is curved greatly to such an extent that second target object 3 (upper member) cannot be placed thereon, solder sheet 10 is corrected on another flat plate so as to be parallel thereto because second target object 3 (upper member) is to be placed thereon in the next step.

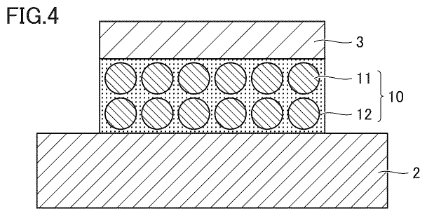

Next, as a third step (S3), second target object 3 (upper member) is placed on solder sheet 10 (see FIG. 4).

It should be noted that the above-described tack material may be applied between bonding-target member (upper member) 1 and solder sheet 10 in order to fix the installation position.

It should be noted that each of the surfaces of the bonding-target members (first target object 2 and second target object 3) on the bonding side is preferably provided with Cu or Ni plating or is preferably coated with an Au film, an Ag film, a Pt film, or the like on the order of several ten nm.

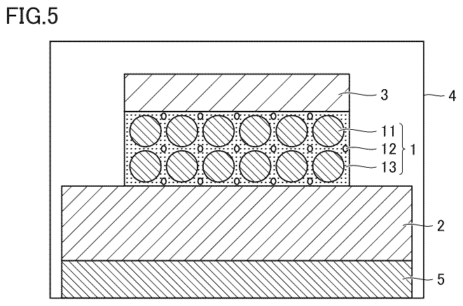

Next, as a fourth step (S4), the stack of the respective members obtained in the above-described steps was placed on a hot plate 5 in a heating furnace 5 (see FIG. 5). Then, formic acid, which is a representative organic acid that can reduce an oxide film, was sealed in heating furnace 5, and solder sheet 10 was melted by performing heating at 180 °C for 5 minutes and then performing heating at 260 °C for 3 minutes, thereby forming bonding member 1.

Here, low melting-point phase 12 and metal particles 11 in solder sheet 10 form a compound due to thermal diffusion. A formation ratio of the compound (intermetallic compound) of metal particles 11 and Sn is changed depending on the particle sizes and amount of addition of metal particles 11. Therefore, it is preferable to adjust the particle sizes and amount of addition of metal particles 11 such that low melting-point phase 12 remains.

A reason therefor is as follows: first, when a multiplicity of portions of bonding member 1 are formed by metal particles 11 and intermetallic compound 13, Sn of low melting-point phase 12 cannot be deformed, and therefore there is no problem in terms of the bonding reliability.

On the other hand, each of the surfaces of general-purpose bonding-target members (first target object 2 and second target object 3) may have roughness, and the surface roughness (unevenness) may be on the order of several μm. Therefore, when bonding is performed without application of pressure, an amount of low melting-point phase 12 corresponding to the volume of the unevenness of the surface also needs to wet and spread. However, when a large amount of metal particles 11 are present, the surface area of metal particles 11 in solder sheet 10 becomes large, low melting-point phase 12 preferentially reacts with metal particles 11, and low melting-point phase 12 does not sufficiently wet the surface of the bonding-target member.

Therefore, in the present embodiment, it is preferable to adjust the particle sizes and amount of addition of metal particles 11 such that low melting-point phase 12 remains. For example, the particle sizes (average particle size: D50) of metal particles 11 added to solder sheet 10 are each 5 to 20 μm, and a blending ratio of the metal particles in solder sheet 10 is 8 to 30 mass %.

It should be noted that when there is no concern about damage to the bonding-target members, the bonding may be performed under application of pressure.

Next, as a fifth step (S5), the sample having bonding member 1 formed was placed on a cooling plate 6 for the sake of cooling (see FIG. 6).

On this occasion, in a case where the solder bonding member is composed of a material that is completely melted such as ordinary solder, there is a possibility that a bonding-target member (the upper member or the lower member) is warped or undulated (unevenness is formed) due to thermal contraction, disadvantageously. Therefore, it is desirable to gradually perform cooling in the cooling step. For example, cooling to 100 °C is performed generally within 60 seconds; however, in order to reduce the warpage, the cooling to 100 °C may be performed for about 400 seconds.

Since the main component of metal particles 11 is Ni having a thermal expansion coefficient lower than that of Sn in the present disclosure, an amount of thermal contraction of solder sheet 10 is small, the thermal expansion coefficient of each of the bonding-target members (first target object 2 and second target object 3) is 3×10⁻⁶/K or more and less than 13×10⁻⁶/K, and the difference between the thermal expansion coefficient of first target object 2 and the thermal expansion coefficient of second target object 3 is less than 5×10⁻⁶/K, with the result that the warpage can be small and residual stress generated in bonding member 1 can also be low. Therefore, the time of the cooling step does not particularly need to be long.

In an actual application thereof to a power module, for example, a circuit board having a semiconductor element and a circuit pattern formed thereon may be bonded to a heat radiation plate with bonding member 1 being interposed therebetween. Bonding member 1 (solder sheet 10) can be applied to a die-bond portion, a base attachment portion, or the like of the power module regardless of a bonding area size.

It should be noted that an oxygen concentration in solder sheet 10 is also important. Each of metal particles 11 contains Ni, which is likely to be oxidized, and the surface area of metal particles 11 is large. Therefore, even when the surfaces of a slight amount of metal particles 11 are oxidized, the oxidation progresses from the interfaces of metal particles 11 to result in a large amount of oxidation as a whole, thereby greatly affecting the wettability. Therefore, when the oxygen concentration in solder sheet 10 is high, an excellent bonding member cannot be formed unless it is stored in a vacuum desiccator or the like. Therefore, in order to form an excellent bonding member, the oxygen concentration in solder sheet 10 is preferably more than 0 and less than 500 ppm.

### EXAMPLES

Hereinafter, the present disclosure will be described more in detail with reference to examples, but the present disclosure is not limited to these examples.

### Test Example 1

Bonding samples (samples 1 to 7) were produced in the procedure described in the above-described embodiments with reference to FIG. 1 with the thermal expansion coefficients of first target objects 2 and second target objects 3 being changed as shown in Table 1. It should be noted that the particle size (average particle size: D50) of metal particles 11 added to each solder sheet 10 is 10 μm.

As each first target object 2, a CuMo alloy plate (thickness: 1 mm; size: 20 mm×20 mm) was used. The outermost surface of the CuMo alloy plate was pure copper and was not provided with plating. In these CuMo alloy sheets, blending ratios of Cu and Mo were changed to change the thermal expansion coefficients as shown in Table 1. It should be noted that an invar alloy was used as a first target object having a thermal expansion coefficient of 2.

It should be noted that in the case of a DBC (Direct Bonded Copper) substrate or a CIC (Copper-Invar-Copper) substrate, the thermal expansion coefficient can be appropriately adjusted by the thicknesses of the three layers included in the substrate.

Each of second target objects 3 has a thickness of 100 μm and a size of 10 mm×10 mm. The thermal expansion coefficients of second target objects 3 were changed as shown in Table 1 in accordance with the blending ratios of the CuMo alloy and the invar alloy in the same manner as in first target objects 2.

In order to prevent the wettability from being different depending on a type of bonding-target member, Ni plating having a thickness of 3 μm was applied to each of the surfaces of first target object 2 and second target object 3 on the bonding side.

The bonding samples of the combinations shown in Table 1 and obtained as described above were subjected to a high-speed thermal shock test that simulates a power cycle test. Specifically, the thermal shock test was performed by repeatedly performing 100000 cycles with one cycle consisting of 10 seconds of ON of electrical conduction (reached temperature: 175 °C) and 10 seconds of OFF of electrical conduction (reached temperature: 50 °C).

After the thermal shock test, a cross section of the layer of the bonding member of each bonding sample in the thickness direction was formed and a transmission X-ray image of the cross section was binarized for image analysis, thereby measuring a ratio of the area of voids generated in the bonding member to the area (100%) of the entire bonding member in the cross section. When the ratio of the area of the voids was 10% or more, it was evaluated as “NG”, whereas when the ratio of the area of the voids was less than 10%, it was evaluated as “OK” because there was no practical problem. Evaluation results are shown in Table 1.

TABLE 1

| | Thermal Expansion Coefficient [10⁻⁶/K] | | | |
|---|---|---|---|---|
| | Second Target | First Target | | |
| | Object | Object | | Evaluation |
| | (3 in FIG. 6) | (2 in FIG. 6) | Difference | Result |
| Sample 1 | 2.0 | 6.0 | 4.0 | NG |
| Sample 2 | 3.0 | 7.3 | 4.3 | OK |
| Sample 3 | 7.3 | 11.8 | 4.5 | OK |
| Sample 4 | 12.5 | 17.3 | 4.8 | OK |
| Sample 5 | 12.5 | 18.4 | 5.9 | NG |
| Sample 6 | 7.3 | 12.5 | 5.2 | NG |
| Sample 7 | 11.8 | 17.2 | 5.4 | NG |

In view of the results shown in Table 1, it is understandable that when each of the thermal expansion coefficients of first target object 2 and second target object 3 is 3×10⁻⁶/K (3.0×10⁻⁶/K) or more and less than 13×10⁻⁶/K (13.0×10⁻⁶/K) and the difference between the thermal expansion coefficient of first target object 2 and the thermal expansion coefficient of second target object 3 is less than 5×10⁻⁶/K (5.0×10⁻⁶/K), the evaluation result is OK and voids are less likely to be generated in the bonding member after the high-speed thermal shock test. Therefore, according to the present disclosure, it is understandable that it is possible to provide: a bonding member having high bonding reliability for a power cycle in a semiconductor device that is operated at a high temperature; and a semiconductor device using the bonding member.

It should be noted that these results are also associated with the thermal expansion coefficient of the bonded portion (the bonding member and the bonding-target member). As described above, a tensile-compressive stress in the lateral direction is applied to a bonding member restrained by bonding-target members (first target object 2 and second target object 3) to generate a crack in the vertical direction. That is, when the thermal expansion coefficient of bonding member 1 is small, the stress generated can also be small. In the present disclosure, metal particles 11 each containing Ni as a main component are used. It is difficult to predict, from public documents, to what degree the thermal expansion coefficient of bonding member 1 employing metal particles 11 affects the bonding reliability.

As a result of actually reviewing the thermal expansion coefficient and the like of bonding member 1 by the present inventors, it was found that excellent results (samples 2 to 4 in Table 1) can be obtained when the thermal expansion coefficient of the bonding member is 16×10⁻⁶/K or more and less than 20×10⁻⁶/K and the ratio of the area of the low melting-point phase (phase containing Sn as a main component and having a melting point of less than 300 °C) to the area (100%) of the entire bonding member in the cross section of the bonding member (cross section of the layer of the bonding member in the thickness direction) is 2% or more and less than 20% (i.e., when the ratio of the amount of low melting-point phase 12 to the total amount of bonding member 1 is 2 volume % or more and less than 20 volume %).

The embodiments and examples disclosed herein are illustrative and non-restrictive in any respect. The scope of the present disclosure is defined by the terms of the claims, rather than the embodiments described above, and is intended to include any modifications within the scope and meaning equivalent to the terms of the claims.

### REFERENCE SIGNS LIST

1 bonding member; 10 solder sheet; 11 metal particle; 12 low melting-point phase; 13 intermetallic compound; 2 first target object (heat radiation plate); 3 second target object (circuit board); 4 heating furnace; 5 hot plate; 6 cooling plate.

1. A bonding member to bond a first target object and a second target object,
the bonding member comprising:
a metal particle containing Ni as a main component;
a low melting-point phase containing Sn as a main component and having a melting point of less than 300 °C; and
an intermetallic compound having a melting point of 300 °C or more and resulting from interdiffusion between Sn and the metal particle, wherein
a ratio of an amount of the low melting-point phase to a total amount of the bonding member is 2 volume % or more and less than 20 volume % and the low melting point phase further contains Cu,
each of thermal expansion coefficients of the first target object and the second target object is 3×10⁻⁶/K or more and less than 13×10⁻⁶/K, and a difference between the thermal expansion coefficient of the first target object and the thermal expansion coefficient of the second target object is less than 5×10⁻⁶/K, and
a thermal expansion coefficient of the bonding member is 16×10⁻⁶/K or more and less than 20×10⁻⁶/K.

2. The bonding member according to claim 1, wherein the low melting-point phase further contains Ag.

3. The bonding member according to claim 2, wherein the metal particle further contains at least one component selected from a group consisting of Fe, Cr, C, Cu, and Si.

4. The bonding member according to claim 3, wherein
the first target object is a heat radiation plate, and
the second target object is a circuit board having a semiconductor element and a wiring circuit.

5. A semiconductor device comprising:
a heat radiation plate; and
a circuit board having a semiconductor element and a wiring circuit, wherein
the heat radiation plate and the circuit board are bonded with the bonding member according to claim 4 being interposed between the heat radiation plate and the circuit board.

6. The bonding member according to claim 1, wherein the metal particle further contains at least one component selected from a group consisting of Fe, Cr, C, Cu, and Si.

7. The bonding member according to claim 6, wherein
the first target object is a heat radiation plate, and
the second target object is a circuit board having a semiconductor element and a wiring circuit.

8. A semiconductor device comprising:
a heat radiation plate; and
a circuit board having a semiconductor element and a wiring circuit, wherein
the heat radiation plate and the circuit board are bonded with the bonding member according to claim 7 being interposed between the heat radiation plate and the circuit board.

9. The bonding member according to claim 1, wherein
the first target object is a heat radiation plate, and
the second target object is a circuit board having a semiconductor element and a wiring circuit.

10. A semiconductor device comprising:
a heat radiation plate; and
a circuit board having a semiconductor element and a wiring circuit, wherein the heat radiation plate and the circuit board are bonded with the bonding member according to claim 9 being interposed between the heat radiation plate and the circuit board.

11. The bonding member according to claim 2, wherein
the first target object is a heat radiation plate, and
the second target object is a circuit board having a semiconductor element and a wiring circuit.

12. A semiconductor device comprising:
a heat radiation plate; and
a circuit board having a semiconductor element and a wiring circuit, wherein
the heat radiation plate and the circuit board are bonded with the bonding member according to claim 11 being interposed between the heat radiation plate and the circuit board.
